(19) United States
(12) Patent Application Publication
(10) Pub. No.: US 2019/0324060 A1
(43) Pub. Date: Oct. 24, 2019

(54) OSCILLOSCOPE SYSTEM

(71) Applicant: Dell Products L.P., Round Rock, TX (US)

(72) Inventors: Vasa Mallikarjun Goud, Secunderabad (IN); Bhyrav M. Mutnury, Austin, TX (US); Umesh Chandra, Santa Cruz, CA (US)

(21) Appl. No.: 15/956,567

(22) Filed: Apr. 18, 2018

(51) Int. Cl. G01R 13/22

(52) U.S. Cl. CPC G01R 13/22

(57) ABSTRACT

An oscilloscope system includes a chassis with an input signal port and a display system located on the chassis that are both coupled to a measurement engine. The measurement engine captures, via an input signal probe that is coupled to the input signal port and a device under test, a first output test pattern that is generated by the device under test in response to a first input test pattern that is received from a transmitter device. The measurement engine derives, using the first input test pattern, a transfer function for the device under test. The measurement engine captures a second input test pattern that is received from the transmitter device and that is different than the first input test pattern and mathematically convolutes, using the second input test pattern, the transfer function for the device under test to generate a reference measurement.

### BACKGROUND

The present disclosure relates generally to information handling systems, and more particularly to an oscilloscope system for validating information handling systems.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems sometimes undergo testing and validation. For example, server computing devices, tablet computing devices, mobile phones, laptop/notebook computing devices, and/or a variety of other computing devices, are sometimes subject to testing and validation by designers that use oscilloscopes to determine, for example, signal integrity of signals transmitted using those computing devices. Similarly, oscilloscopes may be used for testing and validation of components of the computing devices such as, for example, a Hard Disk Drive (HDD), Peripheral Component Interconnect Express (PCIe) adapters, Dual In-Line Memory Modules (DIMMs), and other computing device hardware components known in the art. For example, venders often use oscilloscopes to qualify computing device hardware components that support high speed interfaces (e.g., Serial Attached SCSI (SAS), Serial AT Attachment (SATA), Peripheral Component Interconnect Express (PCIe), and a Double Data-Rate (DDR) interface).

However, as the signal speeds in computing devices continue to increase, limitations in oscilloscopes are becoming more apparent. For example, it has been found that oscilloscope measurements of computing devices are difficult to correlate with simulation measurements obtained from running a simulation of that computing device using a simulation system. FIG. 8 includes a graph 800 that illustrates how conventional oscilloscope measurements 802 and simulation measurements 804 (as interpreted via eye diagrams) become mismatched as signal speeds increase. One of the reasons for the correlation mismatch is that the oscilloscope measurement data often does not include the same number of sample points as the simulation measurement data, as in order to obtain the same sampling density as simulation measurements, oscilloscope measurements must be made over a relatively long time period (e.g., multiple days), which in some cases is impractical. In another example of conventional oscilloscopes limitations, conventional oscilloscopes lack repetitive and consistent measurements as the signal speeds increase. In various experiments of an HDD that was measured multiple times using the same oscilloscope and software version, a run-to-run variation of up to 100 mV between different bit patterns occurred. Furthermore, even when the bit pattern was locked, a run-to-run variation of approximately 40 mV occurred. In yet another example of conventional oscilloscope limitations, conventional oscilloscopes do not provide any ability to debug the channel that is under test, and that inability to debug or otherwise determine which aspect of the channel is causing an issue is due to the limited number of sample points that are collected from the oscilloscope measurements.

Accordingly, it would be desirable to provide an improved oscilloscope system.

### SUMMARY

According to one embodiment, an information handling system (IHS) includes an input signal port; a processing system coupled to the input signal port; and a memory system that is coupled to the processing system and that stores instruction that, when executed by the processing system, cause the processing system to provide a measurement engine that is configured to: capture, via an input signal probe that is coupled to the input signal port and a device under test, a first output test pattern that is generated by the device under test in response to a first input test pattern that is received from a transmitter device; derive, using the first input test pattern, a transfer function for the device under test; capture, via the input signal probe, a second input test pattern that is received from the transmitter device and that is different than the first input test pattern; and mathematically convolute, using the second input test pattern, the transfer function for the device under test to generate a reference measurement.

### BRIEF DESCRIPTION OF THE DRAWINGS

FIG. 1 is a schematic view illustrating an embodiment of an information handling system.

FIG. 2 is a schematic view illustrating an embodiment of an oscilloscope testing system.

FIG. 3A is a perspective view illustrating an embodiment of an oscilloscope used in the oscilloscope testing system of the FIG. 2.

FIG. 3B is a schematic view illustrating an embodiment of the oscilloscope of FIG. 3A.

FIG. 4 is a schematic view illustrating an embodiment of a simulation system used in the oscilloscope testing system of FIG. 2.

FIG. 5 is a flow chart illustrating an embodiment of a method for obtaining oscilloscope measurements.

FIG. 6 is a flow diagram illustrating an embodiment of a calculation of the oscilloscope measurements obtained in the method of FIG. 5.

FIG. 7 is a chart illustrating embodiments of an eye diagram for signals transmitted through a device under test using systems and methods of the present disclosure, as compared to an eye diagram for signals transmitted through a device under test using conventional systems and methods.

FIG. 8 is a graph illustrating an embodiment of a mismatch between simulation measurements and conventional oscilloscope measurements as signal speed increases through a device under test.

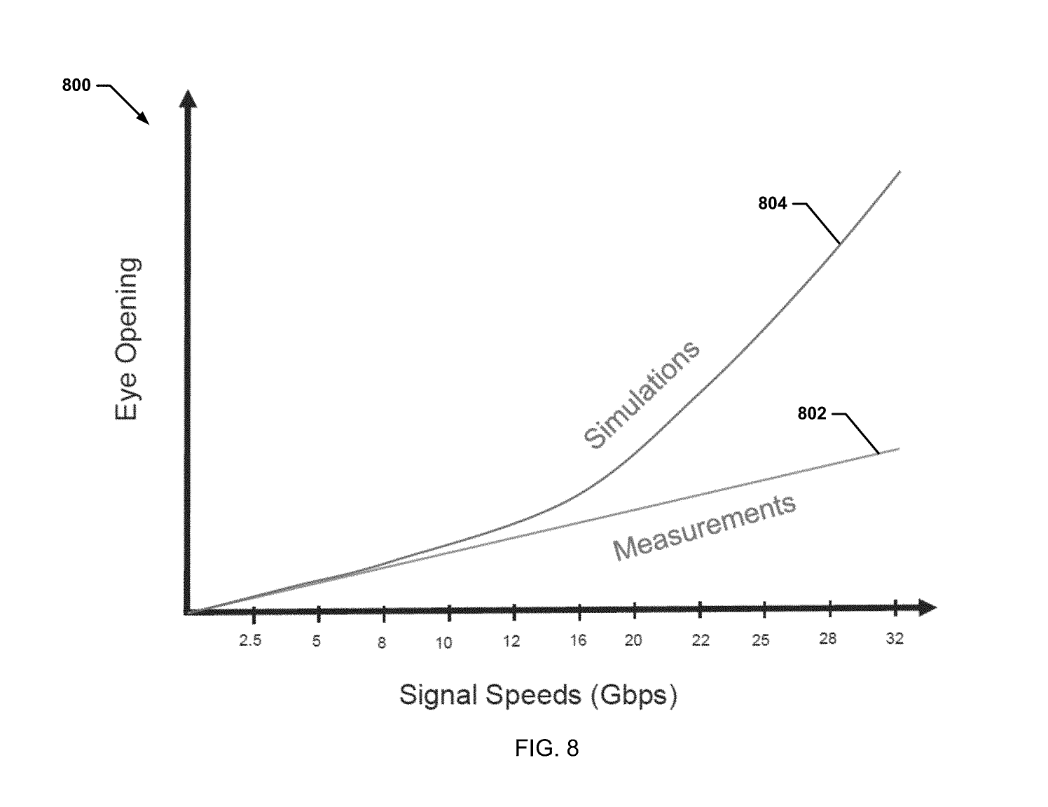

### DETAILED DESCRIPTION

For purposes of this disclosure, an information handling system may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, mobile device (e.g., personal digital assistant (PDA) or smart phone), server (e.g., blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

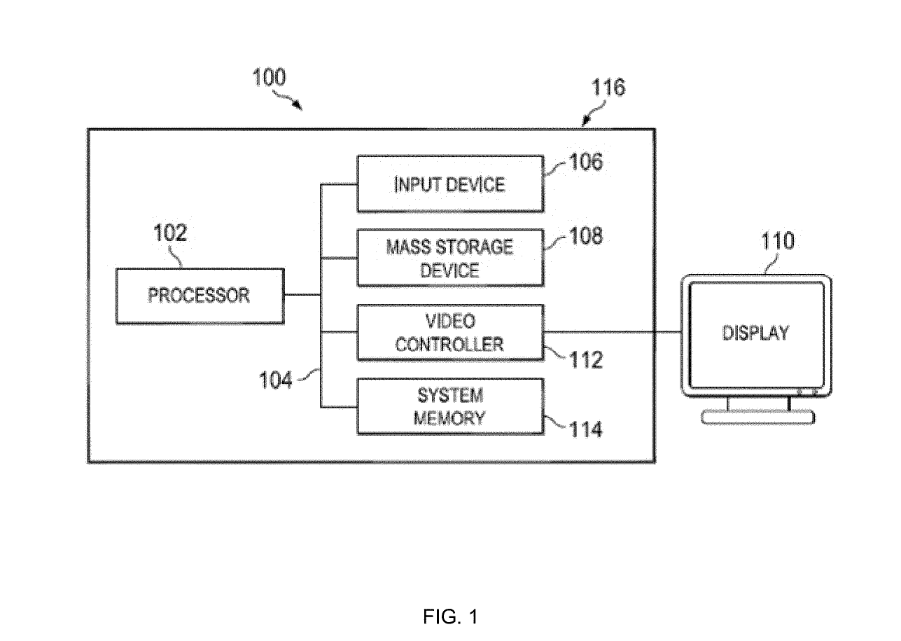

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

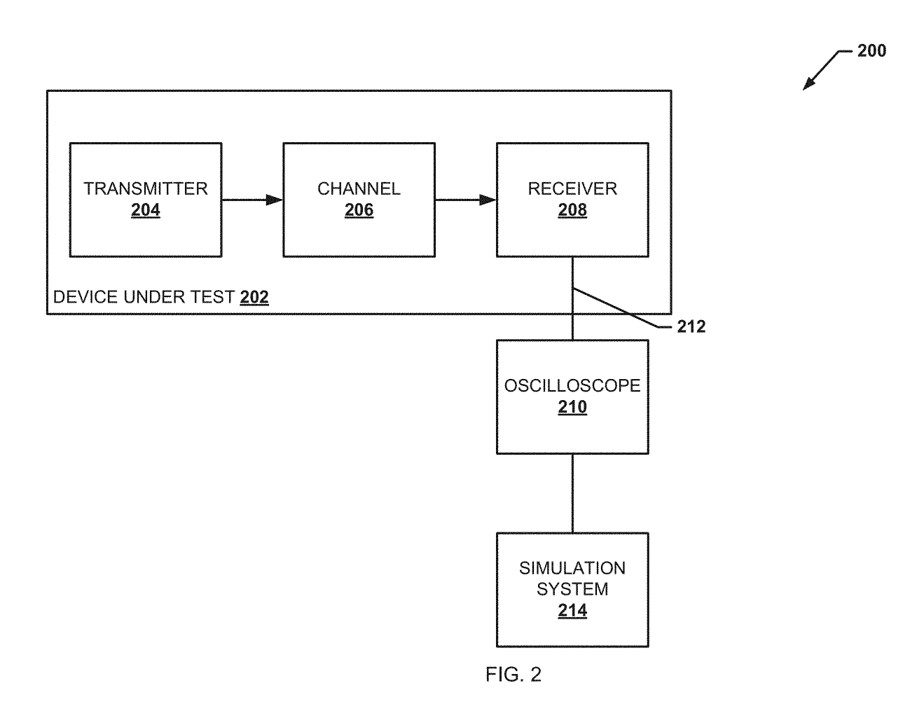

Referring now to FIG. 2, an embodiment of an oscilloscope testing system 200 is illustrated. In the illustrated embodiment, the oscilloscope testing system 200 includes a device under test 202, which may be provided by the IHS 100 discussed above with reference to FIG. 1, and/or may include some or all of the components of the IHS 100. However, one of skill in the art will recognize that the device under test 202 may be provided by other computing devices (e.g., desktop computing device(s), laptop/notebook computing device(s), tablet computing device(s), mobile phone(s), networking device(s) and/or other computing devices that would be apparent to one of skill in the art in possession of the present disclosure), or one or more components of a computing device (e.g., a Hard Disk Drive (HDD), a Peripheral Component Interconnect Express (PCIe) adapter, a Dual In-Line Memory Module (DIMM), and/or other hardware components or combination of hardware components that that would be apparent to one of skill in the art in possession of the present disclosure) while remaining within the scope of the present disclosure as well.

The device under test 202 may include a transmitter device 204 that is configured to generate signals such as, for example, a series of analog pulses that depend on input digital signals, and transmit the signals across a channel 206 in the device under test 202 to a receiver device 208 in the device under test 202. The channel 206 may provide the electrical path between the transmitter device 204 and the receiver device 208, which may include a high speed serial link that is provided by one or more printed circuit board (PCB) traces, vias, connectors, and/or other channel components that would be apparent to one of skill in the art in possession of the present disclosure. The receiver device 208 may be configured to amplify the received analog signal, and sample those received analog signals to output a corresponding digital bit stream. While an embodiment of the device under test 202 is illustrated as including the transmitter device 204, channel 206, and the receiver device 208, one of skill in the art in possession of the present disclosure would recognize that the device under test 202 may include any one, or any combination of, the transmitter device 204, channel 206, and the receiver device 208 (e.g., the device under test 202 may include only the channel 206) while remaining within the scope of the present disclosure. Furthermore, one of skill in the art in possession of the present disclosure will recognize that the embodiment of the device under test 202 illustrated in FIG. 2 is greatly simplified to provide an clarified example of a device that may be tested according to the teachings of the present disclosure, and a wide variety of additional and/or different components may be included in a device under test while remaining within the scope of the present disclosure.

The oscilloscope testing system 200 also includes an oscilloscope 210 that may be provided by the IHS 100 discussed above with reference to FIG. 1, and/or that may include some or all of the components of the IHS 100. For example, the oscilloscope 210 may be provided by a digital storage oscilloscope, a Personal Computer (PC)-based oscilloscope, an analog storage oscilloscope, and/or any other oscilloscope that would be apparent to one of skill in the art in possession of the present disclosure. The oscilloscope 210 may be coupled to the receiver device 208 via a probe 212 in order to, for example, receive output signals generated by the device under test 202 through the probe 212. The oscilloscope 210 may be configured to display one or more output signals received from the device under test 202 as a two-dimensional plot of the output signals as a function of time or frequency. While the probe 212 is illustrated as being coupled to the receiver 208, one of skill in the art in possession of the present disclosure will recognize that the probe 212 may be coupled to various locations on the device under test 202 between the transmitter device 204 and the receiver device 208 while remaining within the scope of the present disclosure.

The oscilloscope system 200 may optionally include a simulation system 214 which may be provided by the IHS 100 discussed above with reference to FIG. 1, and/or may include some or all of the components of the IHS 100. In specific examples, the simulation system 214 may be provided by desktop computing device(s), laptop/notebook computing device(s), tablet computing device(s), mobile phone(s), and/or any other computing device that would be apparent to one of skill in the art in possession of the present disclosure. The simulation system 214 may be configured to simulate the device under test 202, and well as provide any test signals through the simulated device under test. For example, the simulation system 214 may use one or more mathematical models to replicate the behavior of the actual physical device under test 202 in order to provide the simulation. The simulation system 214 may be coupled to the oscilloscope 210 to receive oscilloscope measurements from, and/or transfer simulation measurements to, the oscilloscope 210. For example, the simulation system 214 may be directly coupled to the oscilloscope 210 through a wired and/or wireless connection, and/or may be indirectly coupled to the oscilloscope 210 through a network. While a specific embodiment of the oscilloscope testing system 200 is illustrated and described herein, one of skill in the art in possession of the present disclosure will recognize that a wide variety of modification to the components and configuration of the oscilloscope testing system 200 will fall within the scope of the present disclosure.

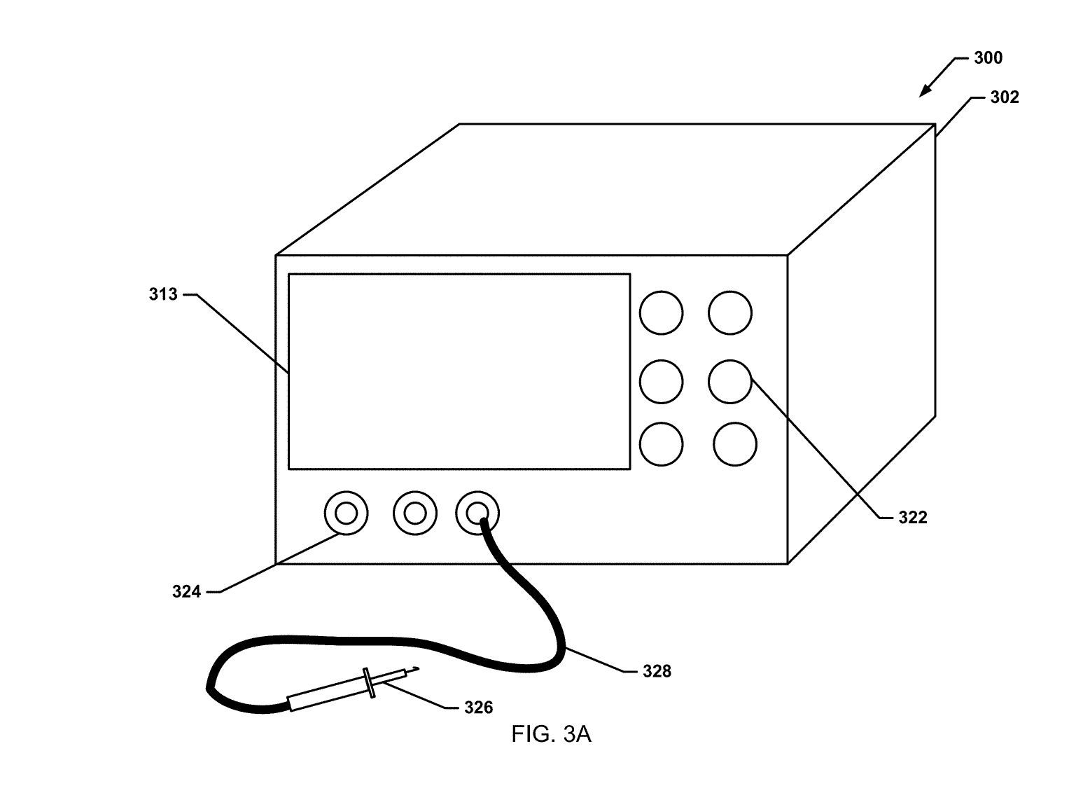

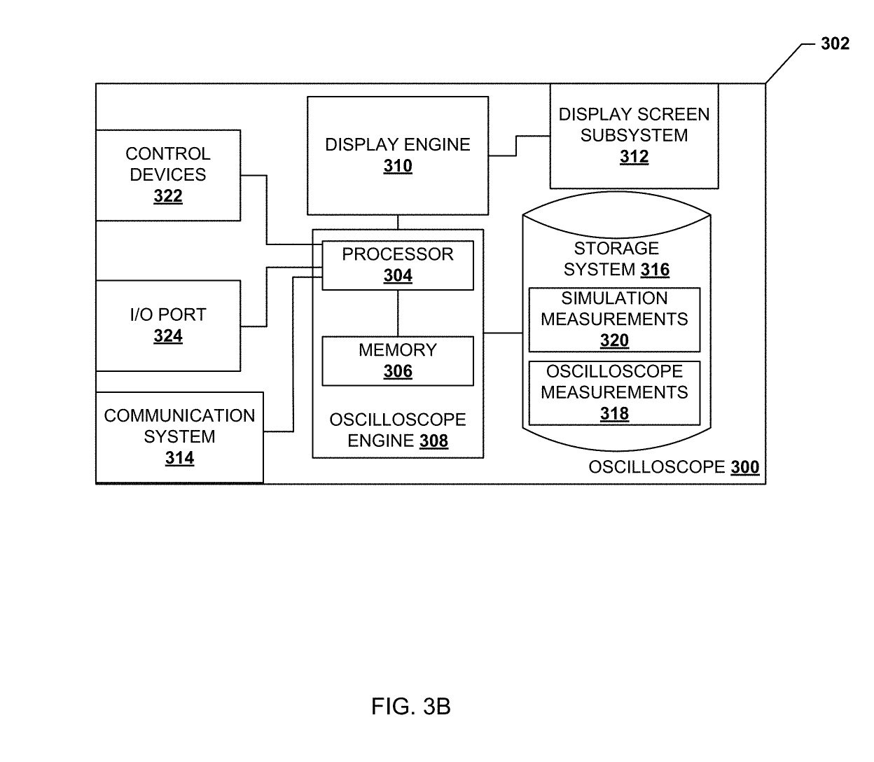

Referring now to FIGS. 3A and 3B, an embodiment of an oscilloscope 300 is illustrated that may be the oscilloscope 210 discussed above with reference to FIG. 2. As such, the oscilloscope 300 may be the IHS 100 discussed above with reference to FIG. 1, and/or may include some or all of the components of the IHS 100. In different embodiments, the oscilloscope 300 may include any digital storage oscilloscope, PC-based oscilloscope, analog storage oscilloscope, and/or any other oscilloscope that would be apparent to one of skill in the art in possession of the present disclosure. The oscilloscope 300 includes an oscilloscope chassis 302 that houses the components of the oscilloscope 300, only some of which are illustrated in FIG. 3B. For example, the oscilloscope chassis 302 may house a processing system 304 and a memory system 306 that is coupled to the processing system 304 and that includes instructions that, when executed by the processing system 304, cause the processing system 304 to provide an oscilloscope engine 308 that is configured to perform the functionality of the oscilloscope engines and the oscilloscopes discussed below.

In another example, the oscilloscope chassis 302 may house an additional processing system (not illustrated, but which may include the processor 102 discussed above with reference to FIG. 1) and a memory system (not illustrated, but which may include the memory 114 discussed above with reference to FIG. 1) that includes instructions that, when executed by the processing system, cause the processing system to provide a display engine 310 that is configured to perform the functions of the display engines and oscilloscopes discussed below. In a specific example, the processing system that provides the display engine 310 may include a graphics processing unit (GPU) that is configured to render oscilloscope measurements as discussed below. However, one of skill in the art in possession of the present disclosure would recognize that the display engine 310 may be provided by the processing system 304 and the memory system 306 while remaining within the scope of the present disclosure as well.

The oscilloscope chassis 302 also houses a display screen subsystem 312 that is coupled to the display engine 310 (e.g., via a coupling between the processing system and the display screen subsystem 312). In an embodiment, the display screen subsystem 312 may be provided by a display device that is integrated into the oscilloscope 300 and that includes a display screen (e.g., a cathode ray tube (CRT) display screen, an light-emitting diode (LED) display screen, a liquid crystal display (LCD) screen, an organic light-emitting diode (OLED) display screen, and/or any other display screen that would be apparent to one of skill in the art in possession of the present disclosure). In another embodiment, the display screen subsystem 312 may be provided by a display device that is coupled directly to the oscilloscope 300 (e.g., a display device coupled to the oscilloscope 300 by a cable or wireless connection). The display screen subsystem 312 may include a display screen via which a graphical user interface (GUI) may be provided by the display engine 310.

The oscilloscope chassis 302 may further house a communication system 314 that is coupled to the oscilloscope engine 308 (e.g., via a coupling between the communication system 314 and the processing system 304) and that may be configured to provide for wireless communication via a network using IEEE 802.11 protocols (Wi-Fi), via wired communications (e.g., the Ethernet protocol), and/or via other communications with the simulation system 214. For example, wireless communications via the communication system 314 may utilize various direct wireless communication protocols such as Bluetooth®, Bluetooth® Low Energy (BLE), near field communication (NFC), infrared data association (IrDA), ANT, Zigbee, and/or other wireless communication protocols that allow for direct wireless communication between devices. The oscilloscope chassis 302 may also house a storage device (not illustrated, but which may be the storage device 108 discussed above with reference to FIG. 1) that provides a storage system 316 that is configured to store oscilloscope measurements 318 that may be provided by the oscilloscope engine 308, and/or simulation measurements 320 that may be provided by the simulation system 214, as discussed in further detail below.

The oscilloscope chassis 302 may also include one or more control devices 322 that may include input devices such as, for example, a focus control, an intensity control, a shape control, a beam finder control, a timebase control, a hold control, a horizontal sensitivity control, a vertical position control, a horizontal position control, a dual-trace control, a delayed-sweep control, a sweep trigger control, and/or any other oscilloscope input/control devices that would be apparent to one of skill in the art in possession of the present disclosure. The oscilloscope chassis 302 may also include one or more input/output (I/O) ports 324 that may be configured to receive the signal that is generated by the device under test 202 and that is to be measured by the oscilloscope engine 308. The I/O port 324 may include a connector such as, for example, a coaxial connector (e.g., BNC or UHF), a binding post connector, a banana plug connector, and/or any other connectors that would be apparent to one of skill in the art in possession of the present disclosure. The I/O port 324 may be configured to couple to a probe 326 (e.g., the probe 212 of FIG. 2) via a cable 328 or other coupling in order to capture signals generated by the device under test 202. However, when the device under test 202 includes its own I/O port to provide an output signal, the I/O port 324 on the oscilloscope 300 may be coupled directly to the I/O port on the device under test 202 via the cable 328 in order to receive the output signal generated by the device under test 202. While a specific embodiment of the oscilloscope 300 is illustrated and described herein, one of skill in the art in possession of the present disclosure will recognize that a wide variety of modification to the components and configurations of the oscilloscope 300 will fall within the scope of the present disclosure as well.

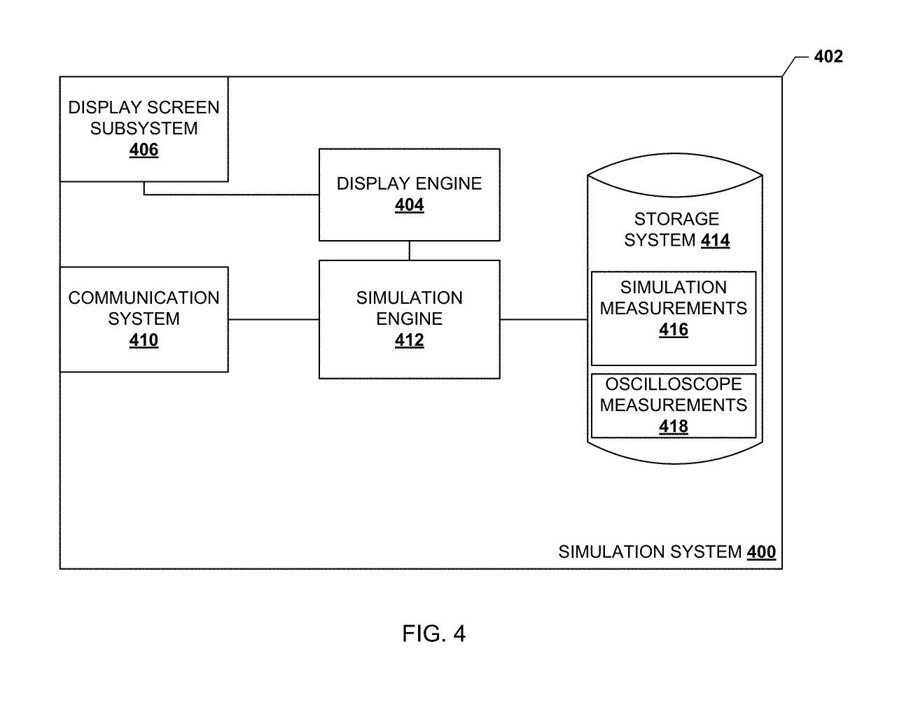

Referring now to FIG. 4, an embodiment of a simulation system 400 is illustrated that may be the simulation system 214 discussed above with reference to FIG. 2. As such, the simulation system 400 may be the IHS 100 discussed above with reference to FIG. 1, and/or may include some or all of the components of the IHS 100. In different embodiments, the simulation system 400 may be provided by a laptop/notebook computer device, a tablet computing device, a mobile phone, a desktop computing device, a server computing device, and/or a variety of other computing devices that would be apparent to one of skill in the art in possession of the present disclosure. In the illustrated embodiment, the simulation system 400 includes a chassis 402 that houses the components of the simulation system 400, only some of which are illustrated in FIG. 4. For example, the chassis 402 may house a processing system (not illustrated, but which may include the processor 102 discussed above with reference to FIG. 1) and a memory system (not illustrated, but which may include the memory 114 discussed above with reference to FIG. 1) that includes instructions that, when executed by the processing system, cause the processing system to provide a display engine 404 that is configured to perform the functions of the display engines and simulation systems discussed below. In a specific example, the processing system that provides the display engine 404 may include a graphics processing unit (GPU) that is configured to render simulation measurements and/or oscilloscope measurements as discussed below.

The chassis 402 also houses a display screen subsystem 406 that is coupled to the display engine 404 (e.g., via a coupling between the processing system that provides the display engine 404 and the display screen subsystem 406). In an embodiment, the display screen subsystem 406 may be provided by a display device that is integrated into a simulation system 400 and that includes a display screen (e.g., a display screen on a laptop/notebook computing device, a tablet computing device, or a mobile phone). In another embodiment, the display screen subsystem 406 may be provided by a display device that is coupled directly to the simulation system 400 (e.g., a display device coupled to a desktop computing device by a cabled or wireless connection). The display screen may be provided by a cathode ray tube (CRT) display screen, an light-emitting diode (LED) display screen, a liquid crystal display (LCD) screen, an organic light-emitting diode (OLED) display screen, and/or any other display screen that would be apparent to one of skill in the art in possession of the present disclosure. The chassis 402 may also house a communication system 410 that is coupled to the display engine 404 (e.g., via a coupling between the processing system that provides the display engine 404 and the communication system 410). In an embodiment, the communication system 410 may be provided by a wireless communication subsystem (e.g., a WiFi communication subsystem, a BLUETOOTH® communication subsystem, and/or other wireless communication subsystems known in the art), a network interface controller (NIC), wired communication subsystem (e.g., an Ethernet communication subsystem), and/or any other communication subsystems that would be apparent to one of skill in the art in possession of the present disclosure.

In an embodiment, the memory system may also include instruction that, when executed by the processing system, cause the processing system to provide an simulation engine 412 that is configured to perform the functions of the simulation engines and simulation systems discussed below. The simulation engine 412 may be configured to provide any of a variety of simulations that would be apparent to one of skill in the art in possession of the present disclosure, and may be configured to communicate with the display engine 404 as discussed below. In a specific example, the simulation engine 412 may provide an operating system for the simulation system 400, as well as any of the applications discussed in the examples below. The chassis 402 may also house a storage device (not illustrated, but which may be the storage device 108 discussed above with reference to FIG. 1) that provides a storage system 414 that is configured to store simulation applications that may be provided by the simulation engine 412. The storage system 414 may also include one or more simulation measurements 416 obtained from a simulation of the device under test 202, and/or the oscilloscope measurements 418 discussed in further detail below. While a specific embodiment of the simulation system 400 is illustrated and described herein, one of skill in the art in possession of the present disclosure will recognize that a wide variety of modification to the components and configuration of the simulation system 400 will fall within the scope of the present disclosure as well.

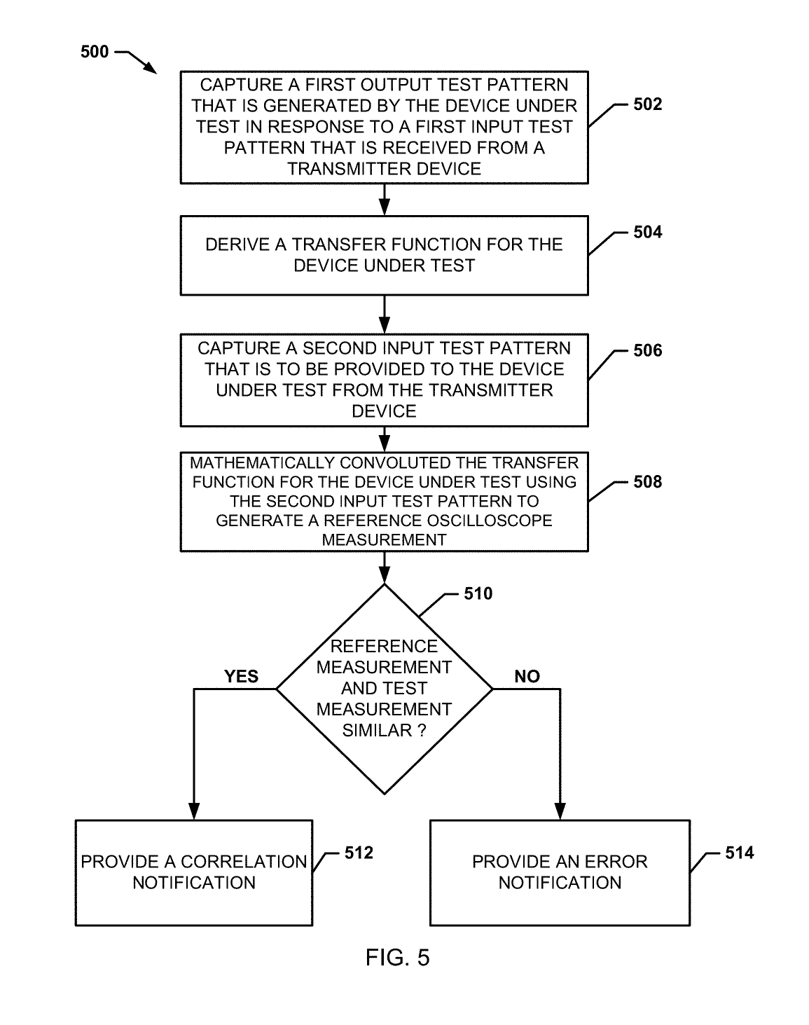

Referring now to FIG. 5, an embodiment of a method 500 for obtaining an oscilloscope measurement at an oscilloscope is illustrated. As discussed above, conventional oscilloscopes lack the ability to correlate oscilloscope measurements with simulation measurements at high data speeds because oscilloscope measurements will include far fewer sample points relative to simulation measurements unless the oscilloscope measurements are obtained over a relatively long time period (e.g., multiple days) that is required to provide the same sampling density as the simulation measurements. Furthermore, conventional oscilloscope measurements are inconsistent as signal speeds increase, and do not provide any ability to debug a device under test. The systems and methods of the present disclosure remedy these issues by creating a reference oscilloscope measurement from a voltage waveform that is obtained from a transfer function for a device under test, where that transfer function mathematically convoluted with an input test pattern provided to the device under test. The voltage waveform may be used to plot an eye diagram, which can be directly compared to an eye diagram plotted using the simulation measurements. Additionally, the eye diagram from the reference oscilloscope measurement may be compared to an eye diagram that was generated conventionally from a test oscilloscope measurement, which was captured from the device under test and generated from the input test pattern provided to the device under test by a transmitter device. The correlation between reference oscilloscope measurement and the test oscilloscope measurement may indicate that something is incorrect with the conventional test oscilloscope measurement.

The method 500 begins at block 502 where a first output test pattern that is generated by the device under test is captured in response to a first input test pattern that is received by the device under test from a transmitter device. In an embodiment of block 502, the transmitter device 204 may receive a first digital input test pattern and, in response, generate and provide an analog test pattern to the channel 206. However, in various embodiments, the transmitter device 204 may include a built in self-test (GIST) circuit that is configured to generate the first input test pattern. For example, the first input test pattern may provide a periodic pattern of logical off bits and logical on bits (e.g., an alternating pattern of 0s and 1s). In some embodiments, the first input test pattern may provide a number of logical off bits and logical on bits to settle reflections in the device under test 202. For example, the length of the input test pattern may be selected to include 500 UIs for logical on bits and 500 UIs for logical off bits. However, one of skill in the art in possession of the present disclosure would recognize that the input test pattern may include fewer logical on bits and/or logical off bits, or more logical on bits and logical off bits, to settle the reflections in the device under test 202. The input test pattern may also be configured such that all sampling points may be captured to derive a transfer function of the device under test 202 from the input test pattern. In some embodiments, the input test pattern may be repeated in a continuous loop until an oscilloscope capture is performed.

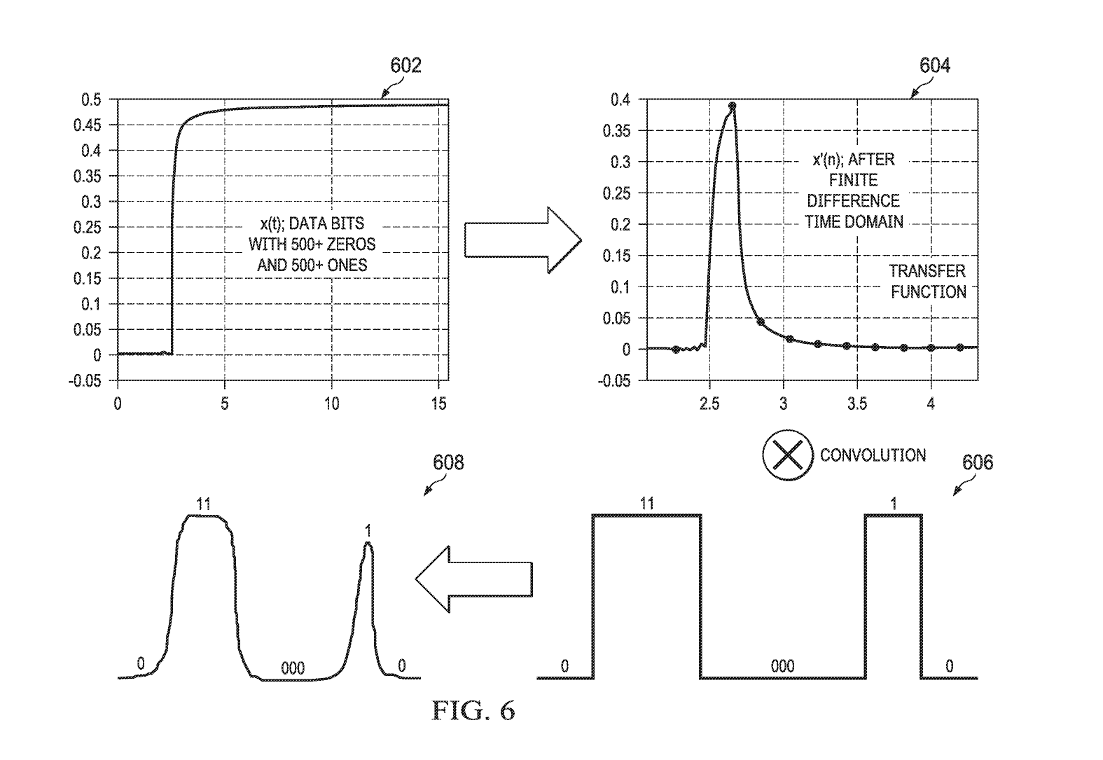

At block 502, the oscilloscope 300 may capture the first output test pattern that is generated from the first input test pattern via the probe 212 that is coupled to the I/O port 324 and the device under test 202. As illustrated in FIG. 6, the first output test pattern may be represented as x(t), as illustrated in graph 602. The function x(t) may be represented as discrete values such as:

x(t)=x(n), where n=0,1,2,3, . . . N−1,N

The method 500 may then proceed to block 504 where a transfer function is derived for the device under test. In an embodiment at block 504, the oscilloscope engine 308 may be configured to estimate the finite difference of x(n) as shown by the equation:

x′(t)=(x(n)1)−x(n))/(Δt);

As illustrated FIG. 6, the oscilloscope engine 308 may use the finite difference of x(n) to capture a transfer function of the device under test represented by graph 604. The oscilloscope engine 308 may then store the transfer function of the device under test 202 in the storage system 316.

The method 500 may then proceed to block 506 where a second input test pattern is captured that is to be provided to the device under test from the transmitter device. In an embodiment of block 506, the transmitter device 204 may receive a second digital input test pattern and, in response, generate and provide an analog test pattern to the channel 206. However, in various embodiments, the transmitter device 204 may include a built in self-test (GIST) circuit that is configured to generate the second input test pattern. In some embodiments, the second digital input test pattern may include a pseudo random bit pattern and/or any other test bit pattern that would be apparent to one of skill in the art in possession of the present disclosure. For example, graph 606 of FIG. 6 illustrates a portion of the second input test pattern, which is different from the first input test pattern. The oscilloscope 300 may capture the second input test pattern via, for example, the positioning of the probe 212 at the transmitter device 204.

The method 500 may then proceed to block 508 where the transfer function for the device under test is mathematically convoluted using the second input test pattern in order to generate a reference oscilloscope measurement. In an embodiment, at block 508, the oscilloscope engine 308 may perform the mathematical convolution. For example, the oscilloscope engine 308 may divide the second input test pattern by the transfer function for the device under test 202 in order to generate the reference oscilloscope measurement. As illustrated in FIG. 6, the second input test pattern of graph 606 may be mathematically convoluted using the transfer function of the graph 604 in order to obtain the reference oscilloscope measurement, which may be the voltage waveform illustrated in graph 608. One of skill in the art in possession of the present disclosure will recognize that the voltage waveform will not have any issues with sampling time because the voltage waveform may have as many sampling points as desired, which may be set by the designer of the device under test 202. Furthermore, the sampling points are a function of ‘Δt’, and may be interpolated into finer numbers if needed.

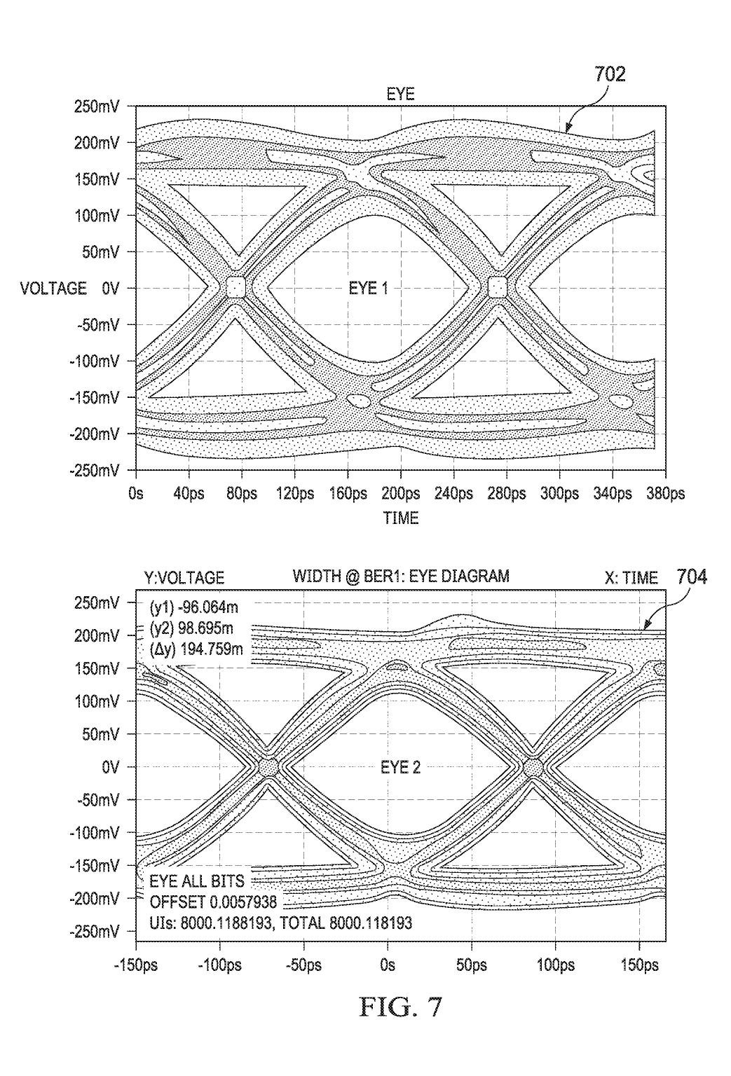

In various examples, the voltage waveform may be displayed by the display engine 310 on a display screen 313 of the display screen subsystem 312. In other examples, the voltage waveform may be used by the oscilloscope engine 308 to generate an eye diagram, which may be displayed by the display engine 310 on the display screen 313 of the display screen subsystem 312. As illustrated in FIG. 7, the oscilloscope engine 308 may generate an eye diagram 702. In various examples, the voltage waveform and/or the eye diagram may be stored as an oscilloscope measurement 318 in the storage system 316. In yet other examples, the voltage waveform and/or the eye diagram may be provided by the oscilloscope 210 to the simulation system 214 via the communication system 314 and the communication system 410. The simulation system 214 may then store the voltage waveform and/or the eye diagram in the storage system 414 as an oscilloscope measurement 418.

The method 500 may continue to block 510 where it is determined whether the reference oscilloscope measurement satisfies a predetermined threshold of similarity with a test measurement. In an embodiment of block 510, the oscilloscope engine 308 may capture a second output test pattern that is generated by the device under test 202 in response to a third input test pattern that is received by the device under test 202 from the transmitter device 204. In some embodiments, the third input test pattern may be the same as the second input test pattern. In some embodiments, the probe 326 may be positioned at the device under test 202 where the first output test pattern was captured when capturing the second output test pattern in order to obtain the test measurement which may provide a test oscilloscope measurement. The test oscilloscope measurement may be a test voltage waveform, a test eye diagram generated from a test voltage waveform, and/or any other test oscilloscope measurement that would be apparent to one or skill in the art in possession of the present disclosure. Referring to the example in FIG. 7, the test oscilloscope measurement may be represented by the eye diagram 704. In some embodiments, the oscilloscope engine 308 may compare the test oscilloscope measurement to the reference oscilloscope measurement to determine whether a predetermined threshold of similarity has been satisfied. For example, the oscilloscope engine 308 may determine whether the eye heights and/or eye widths of the reference eye diagram 702 and the test eye diagram 704 are the 100% similar, 99.5% similar, 99% similar, 95% similar, or any other predetermined level of similarity that would be apparent to one of skill in the art in possession of the present disclosure.

In various embodiments of block 510, the simulation engine 412 may capture a second output test pattern that is generated by a simulation of the device under test 202 in response to a third input test pattern that is received from the transmitter device 204. In various embodiments, the third input test pattern may be the same as the second input test pattern discussed above. The simulation system 214 may capture the second output test pattern in the simulated device under test in order to obtain the test measurement which may include a simulation measurement made in a simulated location corresponding to the physical location on the device under test 202 where the first output test pattern was physically captured. The simulation measurement may be a simulation voltage waveform, a simulation eye diagram generated from a simulation voltage waveform, and/or any other simulation measurement that would be apparent to one or skill in the art in possession of the present disclosure. As illustrated in FIG. 7, the eye diagram 704 may be the simulation eye diagram.

In various examples, the simulation engine 412 may store the simulation measurement as a simulation measurement 416 in the storage system 414, and/or may provide the simulation measurement to the oscilloscope 210 via the communication system 410 and the communication system 314, which may be stored by the storage system 316 as a simulation measurement 320. Thus, the simulation engine 412 and/or the oscilloscope engine 308 may correlate the reference oscilloscope measurement with the simulation measurement to determine whether a predetermined threshold of similarity has been satisfied. For example, the oscilloscope engine 308 and/or the simulation engine 412 may determine whether the eye heights and/or eye widths of the eye diagram 702 and the eye diagram 704 are 100% similar, 99.5% similar, 99% similar, 95% similar, 90% similar, or any other predetermined level of similarity that would be apparent to one of skill in the art in possession of the present disclosure. In various embodiments of block 510, the oscilloscope engine 308 and the simulation system 400 may determine a level similarity between the reference oscilloscope measurement and the test oscilloscope measurement and/or the simulation measurement, and provide a notification as the level of similarity to a designer of the device under test 202.

If at block 510 it is determined that the reference oscilloscope measurement satisfies a predetermined threshold of similarity with the test measurement, the method 500 may proceed to block 512 where a correlation notification is provided that indicates that the test measurement correlates with the reference oscilloscope measurement. For example, the oscilloscope engine 308 may provide the correlation notification to the display engine 310, which may provide the correlation notification for display on the display screen 313 of the display screen subsystem 312. In other examples, the simulation engine 412 may provide the correlation notification to the display engine 404, which may provide the correlation notification for display on a display screen of the display screen subsystem 406.

If at block 510 it is determined that the reference oscilloscope measurement does not satisfy a predetermined threshold of similarity with the test measurement, the method 500 may proceed to block 514 where an error notification is provided that indicates that the test measurement does not correlate with the reference measurement. For example, the oscilloscope engine 308 may provide the error notification to the display engine 310, which may provide the error notification for display on the display screen 313 of the display screen subsystem 312. In other examples, the simulation engine 412 may provide the error notification to the display engine 404, which may provide the error notification for display on a display screen of the display screen subsystem 406. This error notification may indicate to the designer that there is something wrong with the test measurement, and may use any information provided in the notification to perform the test again at the device under test 202 (with the second input test pattern) and/or perform the simulation of the device under test 202 again at the simulation engine 412 (with the third input test pattern, which may require adjustments to the variables provided for the simulation of the device under test 202.) The correlation notification and/or error notification may include information such as differences in eye height and/or eye width, how well the test measurement and the reference oscilloscope measurement correlate, and/or any other information that would be apparent to one of skill in the art in possession of the present disclosure. If there is no correlation, the error notification may include suggestions on conditions to for the designer to check such as, for example, re-sending the second input test pattern, calibrating the oscilloscope 300, checking settings of the oscilloscope 300, and/or any other suggestions that would be apparent one of skill in the art in possession of the present disclosure. In various embodiments, while the oscilloscope 300 and/or the simulation system 400 may provide the correlation notification and/or error notification via as a notification on the display screen subsystems 312 and/or 406, one of skill in the art in possession of the present disclosure would recognize that the correlation notification and/or error notification may be presented to the designer in a wide variety of manners such as, for example, via a user device (e.g., a mobile phone) coupled to the oscilloscope 300 and/or the simulation system 400, via a visual indicator (e.g., one or more LEDs) located on the oscilloscope 300 and/or the simulation system 400, and/or via an audio indicator (e.g., a speaker system) located on the oscilloscope 300 and/or the simulation system 400.

Thus, systems and methods have been described that provide a reference oscilloscope measurement at high signal speeds that may be correlated to test measurements such as, for example, simulation measurements and/or test oscilloscope measurements, when validating a device under test. The systems and methods of the present disclosure provide the reference oscilloscope measurement accurately within hours, as opposed to days with conventional systems that would require infinite persistence to obtain accurate test oscilloscope measurements. This reference oscilloscope measurement of the present disclosure may be correlated with a simulation measurement because that reference oscilloscope measurement may be obtained with a similar number of sampling points as utilized in the simulation measurements. Furthermore, by obtaining a greater number of sampling points with the reference oscilloscope measurement, the sampling points may be better interpolated to decrease run to run variation on test oscilloscope test measurements at the oscilloscope. In addition, the reference oscilloscope measurement may be used to debug which aspect of the device under test is causing an issue when performing validation tests, as well as provide other benefits that would be apparent to one of skill in the art in possession of the present disclosure.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. An oscilloscope system, comprising:
a chassis;
an input signal port located on the chassis;
a display system included on the chassis; and
a measurement engine included in the chassis, coupled to the input signal port and the display system, and configured to:
capture, via an input signal probe that is coupled to the input signal port and a device under test, a first output test pattern that is generated by the device under test in response to a first input test pattern that is received from a transmitter device;
derive, using the first input test pattern, a transfer function for the device under test;
capture, via the input signal probe, a second input test pattern that is received from the transmitter device and that is different than the first input test pattern; and
mathematically convolute, using the second input test pattern, the transfer function for the device under test to generate a reference measurement.

2. The oscilloscope system of claim 1, wherein the measurement engine is further configured to:
generate, using the reference measurement, a first measurement eye diagram; and
display, via the display system, the first measurement eye diagram.

3. The oscilloscope system of claim 2, wherein the measurement engine is further configured to:
capture, via the input signal probe, a second output test pattern that is generated by the device under test in response to the second input test pattern that is received from the transmitter device;
generate, using the second output test pattern, a second measurement eye diagram;
correlate the second measurement eye diagram and the first measurement eye diagram; and
provide, based on the correlation, a correlation notification that is configured to indicate a similarity between the first measurement eye diagram and the second measurement eye diagram.

4. The oscilloscope system of claim 2, further comprising:
a simulation system that is coupled to the measurement engine, wherein the measurement engine is further configured to:
provide, to the simulation system, the first measurement eye diagram, wherein the simulation system is configured to:
perform a simulation using the device under test;
generate, based on the simulation, a simulated eye diagram;
correlate the first measurement eye diagram and the simulated eye diagram; and
provide, based on the correlation, a correlation notification that is configured to indicate a similarity between the first measurement eye diagram and the simulated eye diagram.

5. The oscilloscope system of claim 1, wherein the first input test pattern includes a periodic pattern having an equal number of logical off bits and logical on bits.

6. The oscilloscope system of claim 5, wherein the equal number of logical off bits and logical on bits in the first input test pattern is configured to settle reflections in the device under test.

7. The oscilloscope system of claim 1, wherein the deriving the transfer function for the device under test includes calculating a finite difference of the first output test pattern from which the transfer function is derived.

8. An information handling system (IHS), comprising:
an input signal port;
a processing system coupled to the input signal port; and
a memory system that is coupled to the processing system and that stores instruction that, when executed by the processing system, cause the processing system to provide a measurement engine that is configured to:
capture, via an input signal probe that is coupled to the input signal port and a device under test, a first output test pattern that is generated by the device under test in response to a first input test pattern that is received from a transmitter device;
derive, using the first input test pattern, a transfer function for the device under test;
capture, via the input signal probe, a second input test pattern that is received from the transmitter device and that is different than the first input test pattern; and
mathematically convolute, using the second input test pattern, the transfer function for the device under test to generate a reference measurement.

9. The IHS of claim 8, wherein the measurement engine is further configured to:
generate, using the reference measurement, a first measurement eye diagram; and
display, via a display system, the first measurement eye diagram.

10. The IHS of claim 9, wherein the measurement engine is further configured to:
capture, via the input signal probe, a second output test pattern that is generated by the device under test in response to the second input test pattern that is received from the transmitter device;
generate, using the second output test pattern, a second measurement eye diagram;
correlate the second measurement eye diagram and the first measurement eye diagram; and
provide, based on the correlation, a correlation notification that is configured to indicate a similarity between the first measurement eye diagram and the second measurement eye diagram.

11. The IHS of claim 9, wherein the measurement engine is further configured to:
receive, from a simulation system that is coupled to the measurement engine, a simulated eye diagram that is generated by the simulation system based on a simulation using the device under test;
correlate the first measurement eye diagram and the simulated eye diagram; and
provide, based on the correlation, a correlation notification that is configured to indicate a similarity between the first measurement eye diagram and the simulated eye diagram.

12. The IHS of claim 8, wherein the first input test pattern includes a periodic pattern having an equal number of logical off bits and logical on bits.

13. The IHS of claim 12, wherein the equal number of logical off bits and logical on bits in the first input test pattern is configured to settle reflections in the device under test.

14. The IHS of claim 8, wherein the deriving the transfer function for the device under test includes calculating a finite difference of the first output test pattern from which the transfer function is derived.

15. A method for obtaining oscilloscope measurements of a device under test, comprising:
capturing, via an input signal probe that is coupled to a oscilloscope and a device under test, a first output test pattern that is generated by the device under test in response to a first input test pattern that is received from a transmitter device;
deriving, by the oscilloscope using the first input test pattern, a transfer function for the device under test;
capturing, by the oscilloscope via the input signal probe, a second input test pattern that is received from the transmitter device and that is different than the first input test pattern; and
mathematically convoluting, by the oscilloscope using the second input test pattern, the transfer function for the device under test to generate a reference measurement.

16. The method of claim 15, further comprising:
generating, by the oscilloscope using the reference measurement, a first measurement eye diagram; and
displaying, by the oscilloscope via a display system coupled to the oscilloscope, the first measurement eye diagram.

17. The method of claim 16, further comprising:
capturing, by the oscilloscope via the input signal probe, a second output test pattern that is generated by the device under test in response to the second input test pattern that is received from the transmitter device;
generating, by the oscilloscope using the second output test pattern, a second measurement eye diagram;
correlating, by the oscilloscope, the second measurement eye diagram and the first measurement eye diagram; and
providing, by the oscilloscope and based on the correlation, a correlation notification that is configured to indicate a similarity between the first measurement eye diagram and the second measurement eye diagram.

18. The method of claim 16, further comprising:
receiving, by the oscilloscope from a simulation system, a simulated eye diagram that is generated by the simulation system based on a simulation using the device under test;
correlating, by the oscilloscope, the first measurement eye diagram and the simulated eye diagram; and
providing, by the oscilloscope based on the correlation, a correlation notification that is configured to indicate a similarity between the first measurement eye diagram and the simulated eye diagram.

19. The method of claim 15, wherein the first input test pattern includes a periodic pattern having an equal number of logical off bits and logical on bits.

20. The method of claim 19, wherein the equal number of logical off bits and logical on bits in the first input test pattern is configured to settle reflections in the device under test.
